(19) United States
(12) Patent Application Publication
(10) Pub. No.: US 2026/0198140 A1
(43) Pub. Date: Jul. 9, 2026

(54) SEMICONDUCTOR DEVICE AND MANUFACTURING METHOD THEREOF

(71) Applicant: ENNOSTAR CORPORATION, Hsinchu (TW)

(72) Inventor: ZHEN-KAI KAO, Hsinchu (TW)

(21) Appl. No.: 19/437,130

(22) Filed: Dec. 30, 2025

(30) Foreign Application Priority Data
Jan. 7, 2025 (TW) 114100653

(51) Int. Cl. H10H 20/821; H10H 20/01; H10H 20/841; H10H 20/857; H10H 29/24

(52) U.S. Cl. CPC H10H 20/821; H10H 20/013; H10H 20/841; H10H 20/857; H10H 29/24

(57) ABSTRACT

A semiconductor device and a display device are provided. The semiconductor device includes an epitaxial structure, a first electrode and a second electrode. The epitaxial structure includes a first portion and a second portion adjacent to the first portion. The first portion includes a first semiconductor structure and an active region, and the first portion has a first upper surface and a first side surface. The second portion includes a second semiconductor structure and has a first bottom surface and a second side surface. The active region is located between the first semiconductor structure and the second semiconductor structure. The first electrode covers the first bottom surface. The second electrode covers the first upper surface. In a cross-sectional view, the first side surface is directly connected to the second side surface, the active region has a first maximum width, the second portion has a second maximum width, and a ratio of the first maximum width to the second maximum width is ranging from 0.9 to 1. In the cross-sectional view, a first imaginary line extending along the first lower surface and a second imaginary line extending along the first side surface define a first included angle, the first imaginary line and a third imaginary line extending along the second side surface define a second included angle, the first included angle is different from the second included angle.

### TECHNICAL FIELD

The present disclosure relates to a semiconductor device, and particularly relates to a light-emitting semiconductor device and a display device.

### CROSS REFERENCE TO RELATED APPLICATION

This application claims the right of priority based on TW Application Serial No. 114100653, filed on Jan. 7, 2025, and the content of which is hereby incorporated by reference in its entirety.

### DESCRIPTION OF BACKGROUND ART

Semiconductor devices have a wide range of applications, and research and development of related materials and products have continued in recent years. For example, III-V group semiconductor materials, which include group III and group V elements, can be applied to various semiconductor devices for optoelectronics, such as light-emitting diodes (LEDs), laser diodes (LDs), photodetectors, solar cells, or power devices (e.g., switching devices or rectifiers), and thus can be widely used in fields including lighting, medical care, display, communication, sensing, and power system. Since LEDs have advantages, such as low power consumption, fast response, small size, and long lifespan, LEDs are widely used in various fields. In view of the demand for device miniaturization in recent years, further improvements in the structural design and fabrication processes of semiconductor devices are required.

### SUMMARY OF THE DISCLOSURE

The present disclosure provides a semiconductor device. The semiconductor device includes an epitaxial structure, a first electrode, and a second electrode. The epitaxial structure comprises a first portion and a second portion adjacent to the first portion. The first portion includes a first semiconductor structure and an active region, and the first portion has a first upper surface and a first side surface. The second portion includes a second semiconductor structure and has a first bottom surface and a second side surface. The active region is located between the first semiconductor structure and the second semiconductor structure. The first electrode covers the first lower surface. The second electrode covers the first upper surface. In a cross-sectional view, the first side surface is directly connected to the second side surface, the active region has a first maximum width, the second portion has a second maximum width, and a ratio of the first maximum width to the second maximum width is ranging from 0.9 to 1. In the cross-sectional view, a first imaginary line extending along the first lower surface and a second imaginary line extending along the first side surface define a first included angle, the first imaginary line and a third imaginary line extending along the second side surface define a second included angle, the first included angle is different from the second included angle.

The present disclosure further provides a display device. The display device includes a target carrier and a plurality of pixel units. The plurality of pixel units is disposed on the target carrier. At least one of the plurality of pixel units comprises a first semiconductor device, and the first semiconductor device is a semiconductor device as mentioned above.

### BRIEF DESCRIPTION OF THE DRAWINGS

FIGS. 1A, 1B, 1C, and 1D show schematic cross-sectional views of a semiconductor device according to some embodiments of the present disclosure.

FIG. 1E shows a top view of schematic diagram of a semiconductor device according to some embodiments of the present disclosure.

FIG. 1F shows a schematic perspective view of a semiconductor device according to some embodiments of the present disclosure.

FIG. 2 shows a schematic diagram illustrating a method of a manufacturing method for a semiconductor device according to some embodiments of the present disclosure.

FIGS. 3A-1 to 3A-4 show schematic diagrams illustrating a manufacturing method for a semiconductor device according to some embodiments of the present disclosure.

FIGS. 3B-1 to 3B-2 show schematic diagrams illustrating a manufacturing method for a semiconductor device according to some embodiments of the present disclosure.

FIGS. 4 to 7 and FIGS. 8A to 8B show schematic diagrams illustrating a manufacturing method for a semiconductor device according to some embodiments of the present disclosure.

FIGS. 9 to 13, 14A, and 14B show schematic diagrams illustrating a manufacturing method for a semiconductor device according to some embodiments of the present disclosure.

FIG. 15 shows a schematic top view of a display device according to some embodiments of the present disclosure.

FIG. 16 shows a schematic cross-sectional view of a display device according to some embodiments of the present disclosure.

### DETAILED DESCRIPTION OF PREFERRED EMBODIMENTS

The embodiments of the present disclosure will be described in detail below with reference to the drawings so that those skilled in the art can fully understand the spirit of the present disclosure. It should be noticed that the embodiments for showing the semiconductor device in the present invention are not intended to limit the present invention to these embodiments. In the drawings or the specification, some identical symbols indicate devices having the same or similar structure, function, or principle. Unless otherwise specified, the shapes or dimensions of the elements in the drawings are for illustrative purposes only and are not intended to limit the actual scope. It should be particularly noticed that components not shown or described in the drawings may be implemented in forms known to those skilled in the art.

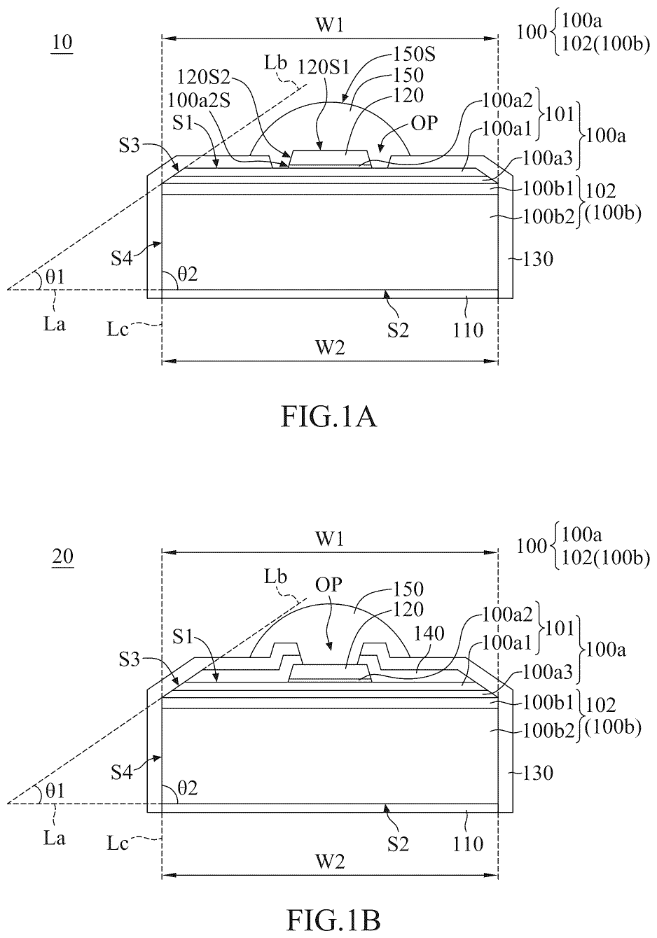

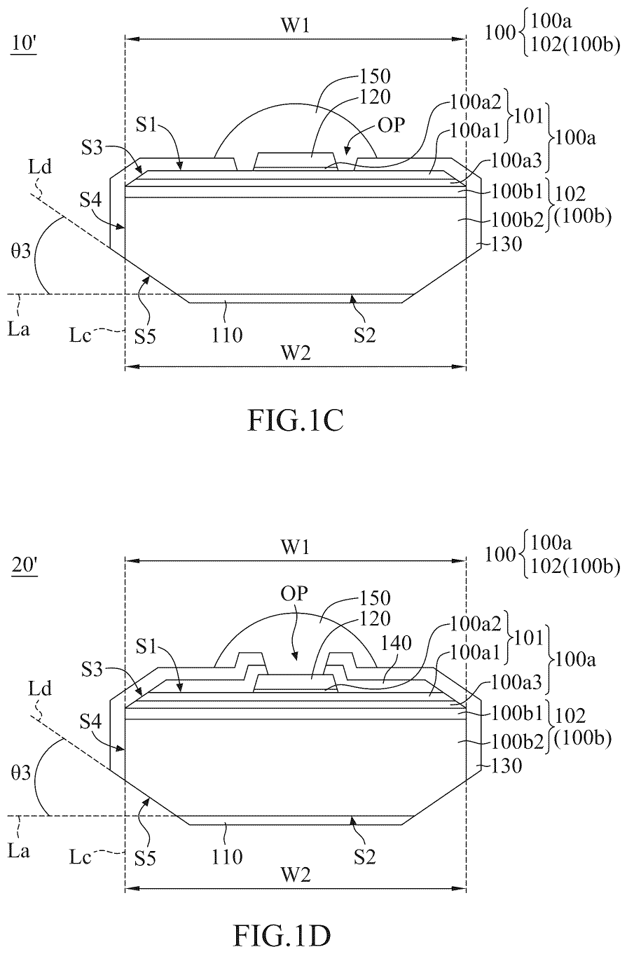

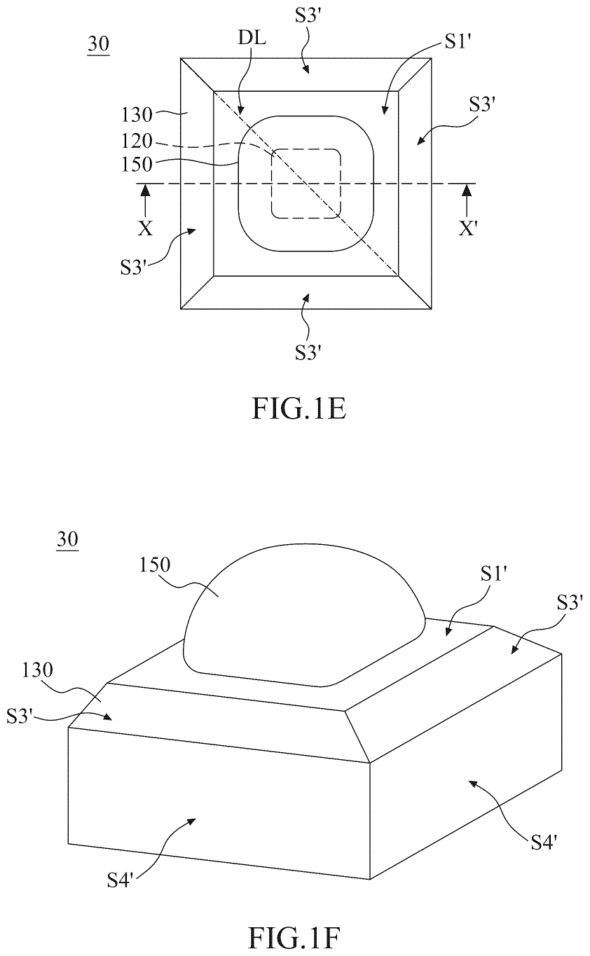

FIGS. 1A to 1D show schematic cross-sectional views of a semiconductor device according to some embodiments of the present disclosure. As shown in FIG. 1A, the semiconductor device 10 includes an epitaxial structure 100. In some embodiments, the epitaxial structure 100 includes a first portion 100a and a second portion 100b adjacent to the first portion 100a. In a cross-sectional view, an external contour of the epitaxial structure 100 may be defined by the first portion 100a and the second portion 100b. The first portion 100a may include a first semiconductor structure 101 and an active region 100a3. The second portion 100b may include a second semiconductor structure 102. The active region 100a3 is located between the first semiconductor structure 101 and the second semiconductor structure 102. The first semiconductor structure 101 and the second semiconductor structure 102 may respectively provide electrons and holes (or holes and electrons), and electrons and holes may recombine in the active region 100a3 to emit radiation having a peak wavelength. The first semiconductor structure 101, the second semiconductor structure 102, and the active region 100a3 may respectively include III-V semiconductor materials. Group III elements may include aluminum (Al), gallium (Ga), or indium (In). Group V elements may include nitrogen (N), arsenic (As), or phosphorus (P). In some embodiments, the first semiconductor structure 101, the second semiconductor structure 102, and the active region 100a3 may not include nitrogen (N).

The epitaxial structure 100 may include a single heterostructure (SH), a double heterostructure (DH), a double-side double heterostructure (DDH), or a multiple quantum wells (MQW) structure. A radiation emitted by the semiconductor device 10 during operation may be visible or non-visible light. Specifically, the peak wavelength may depend on the material composition of the active region 100a3. For example, when the material of the active region 100a3 includes AlGaN, ultraviolet light having a peak wavelength of 250 nm to 400 nm may be emitted; when the material includes InGaN, deep blue or blue light having a peak wavelength of 400 nm to 490 nm, green or yellow light having a peak wavelength of 490 nm to 550 nm, or red light having a peak wavelength of 560 nm to 650 nm may be emitted; when the material includes InGaP or AlGaInP, yellow, orange, or red light having a peak wavelength of 530 nm to 700 nm may be emitted; when the material includes InGaAs, InGaAsP, AlGaAs, or AlGaInAs, infrared light having a peak wavelength of 700 nm to 1700 nm may be emitted. When the active region 100a3 is a MQW structure, it may include a plurality of barrier layers and a plurality of well layers that are alternately stacked. In some embodiments, the barrier layers and the well layers comprise quaternary semiconductor materials or ternary semiconductor materials. Specifically, the barrier layers and the well layers may include aluminum (Al), gallium (Ga), phosphorus (P), or indium (In). In some embodiments, the barrier layers comprise a quaternary semiconductor material (e.g., AlGaInP). In some embodiments, the well layers comprise a ternary semiconductor material (e.g., GaInP or AlInP). A thickness of the active region 100a3 may be ranging from 50 nm to 500 nm (e.g., ranging from 150 nm to 250 nm).

In some embodiments, the first semiconductor structure 101 and the second semiconductor structure 102 may respectively include binary, ternary, or quaternary compound semiconductor materials, such as GaAs, GaP, GaInP, AlInP, or AlGaInP. The first semiconductor structure 101 has a first conductivity type, and the second semiconductor structure 102 has a second conductivity type different from the first conductivity type. In some embodiments, the first conductivity type may be n-type and the second conductivity type may be p-type, or the first conductivity type may be p-type and the second conductivity type may be n-type. The conductivity types of the first semiconductor structure 101 and the second semiconductor structure 102 may be adjusted by adding different dopants. For example, the first semiconductor structure 101 includes a first dopant, and the second semiconductor structure 102 includes a second dopant different from the first dopant. The first and second dopants may be selected from Group II, Group IV, or Group VI elements of the periodic table, such as magnesium (Mg), zinc (Zn), carbon (C), silicon (Si), or tellurium (Te). In some embodiments, doping of the first semiconductor structure 101 and the second semiconductor structure 102 may be performed by in-situ doping during epitaxial growth and/or by ion implantation using a p-type dopant or an n-type dopant after epitaxial growth.

The first semiconductor structure 101 may optionally include a first cover layer 100a1 and a first contact layer 100a2. The first cover layer 100a1 is disposed closer to the active region 100a3 than the first contact layer 100a2. In some embodiments, the first cover layer 100a1 includes n-type or p-type GaAs, GaP, AlInP, and/or GaInP. The first cover layer 100a1 has a thickness be ranging from 10 nm to 500 nm (e.g., ranging from 250 nm to 350 nm). In some embodiments, the first contact layer 100a2 includes n-type or p-type GaAs, GaP, AlInP, and/or GaInP. The first contact layer 100a 2 has a thickness be ranging from 1 nm to 100 nm (e.g., ranging from 20 nm to 60 nm).

The second semiconductor structure 102 may optionally include a second cover layer 100b1 and a second contact layer 100b2. The second cover layer 100b1 is disposed closer to the active region 100a3 than the second contact layer 100b2. In some embodiments, the second cover layer 100b1 includes n-type or p-type GaAs, GaP, AlInP, and/or GaInP. The thickness of the second cover layer 100b1 may be same as or different from the thickness of the first cover layer 100a1. The second cover layer 100b1 has a thickness be ranging from 10 nm to 500 nm (e.g., ranging from 250 nm to 350 nm). In some embodiments, the second contact layer 100b2 includes n-type or p-type GaAs, GaP, AlInP, and/or GaInP. In some embodiments, the second contact layer 100b2 has a thickness ranging from 1000 nm to 4000 nm (e.g., ranging from 2000 nm to 3200 nm).

In some embodiments, in the cross-sectional view, the active region 100a3 has a first maximum width W1, the second portion 100b has a second maximum width W2, and a ratio of the first maximum width W1 to the second maximum width W2 (W1/W2) may be ranging from 0.9 to 1 (e.g., ranging from 0.95 to 0.99). When the ratio of the first maximum width W1 to the second maximum width W2 is within the foregoing range, the area of the active region 100a3 can be maximized, thereby improving light-emitting efficiency. In some embodiments, the second maximum width W2 of the second portion 100b may be the same as a maximum width of the second contact layer 100b2. In some embodiments, the active region 100a3 may have a minimum width, and a ratio of the minimum width to the second maximum width W2 may range from 0.9 to 1 (e.g., ranging from 0.95 to 0.99), which helps maximize the area of the active region 100a3 and improves light-emitting efficiency. In some embodiments, a ratio of a vertical projection area of the active region 100a3 to a vertical projection area of the epitaxial structure 100 (or the second portion 100b) may be ranging from 0.9 to 1 (e.g., ranging from 0.95 to 0.99). In some embodiments, a total thickness of the epitaxial structure 100 is ranging from 1 μm to 5 μm to reduce device thickness, thereby facilitating miniaturization of the device.

As shown in FIG. 1A, the first portion 100a may have a first upper surface S1 and a first side surface S3. The second portion 100b may have a first lower surface S2 and a second side surface S4. In some embodiments, the first upper surface S1 may be a surface of the first cover layer 100a1 adjacent to the first contact layer 100a2, and the first lower surface S2 may be a surface of the second contact layer 100b2 remote from the second cover layer 100b1. Relative to the first lower surface S2, the first side surface S3 and the second side surface S4 may be inclined at different angles.

In some embodiments, the first side surface S3 may include the side surface of the first cover layer 100a1, the side surface of the active region 100a3, and the side surface of the second cover layer 100b1; in other words, the side surface of the first cover layer 100a1, the side surface of the active region 100a3, and the side surface of the second cover layer 100b1 may be substantially coplanar. The second side surface S4 may include the side surface of the second contact layer 100b2. In some embodiments, the first side surface S3 may include the side surface of the first cover layer 100a1 and the side surface of the active region 100a3, and the second side surface S4 may include the side surface of the second cover layer 100b1 and the side surface of the second contact layer 100b2; in other words, the side surfaces of the first cover layer 100a1 and the active region 100a3 may be substantially coplanar, and the side surfaces of the second cover layer 100b1 and the second contact layer 100b2 may be substantially coplanar. In some embodiments, the first side surface S3 may include the side surface of the first cover layer 100a1, the side surface of the active region 100a3, and a portion of the side surface of the second cover layer 100b1; in other words, the side surface of the first cover layer 100a1, the side surface of the active region 100a3, and the portion of the side surface of the second cover layer 100b1 may be substantially coplanar. In some embodiments, the second side surface S4 may include the other portion of the side surface of the second cover layer 100b1 and the side surface of the second contact layer 100b2; in other words, the other portion of the side surface of the second cover layer 100b1 and the side surface of the second contact layer 100b2 may be substantially coplanar.

In the cross-sectional view, a first imaginary line La extending along the first lower surface S2 and a second imaginary line Lb extending along the first side surface S3 define a first included angle θ1, and the first imaginary line La and a third imaginary line Lc extending along the second side surface S4 define a second included angle θ2. The second included angle θ2 may be greater than the first included angle θ1. In some embodiments, the first included angle θ1 may be an acute angle, and the first included angle θ1 may be ranging from 25° to 60° (e.g., ranging from 35° to 45°). In some embodiments, the second included angle θ2 may be an acute angle, a right angle, or an obtuse angle, and the second included angle θ2 may be ranging from 75° to 100° (e.g., ranging from 85° to 90°).

Referring to FIG. 1A, the semiconductor device 10 further includes a first electrode 110 and a second electrode 120. The first electrode 110 may cover all or a portion of the first lower surface S2 and may be in direct contact with the second contact layer 100b2 to establish electrical connection. The second electrode 120 may cover all or a portion of the first upper surface S1 and may be in direct contact with the first contact layer 100a2 on the first upper surface S1 to establish electrical connection. In some embodiments, the second electrode 120 may have a cross-sectional shape such as a trapezoid or a rectangle. The first electrode 110 and the second electrode 120 may each be a single-layer or multilayer structure. The material of the first electrode 110 and the material of the second electrode 120 may be the same or different. In some embodiments, the first electrode 110 and the second electrode 120 may include a transparent conductive material, a metal or an alloy. In some embodiments, the transparent conductive material may include indium tin oxide (ITO), indium oxide (InO), tin oxide (SnO), cadmium tin oxide (CTO), antimony-doped tin oxide (ATO), aluminum-doped zinc oxide (AZO), zinc tin oxide (ZTO), gallium-doped zinc oxide (GZO), indium tungsten oxide (IWO), zinc oxide (ZnO), or indium zinc oxide (IZO). In some embodiments, the metal may be aluminum (Al), chromium (Cr), copper (Cu), tin (Sn), gold (Au), nickel (Ni), titanium (Ti), platinum (Pt), silver (Ag), zinc (Zn), cobalt (Co), germanium (Ge), or beryllium (Be). In some embodiments, the alloy may include two or more of the foregoing metals, such as germanium-gold-nickel (GeAuNi), beryllium-gold (BeAu), germanium-gold (GeAu), or zinc-gold (ZnAu).

The semiconductor device 10 may optionally include a first protective structure 130 covering the epitaxial structure 100, thereby providing insulation and protecting the epitaxial structure 100. In some embodiments, the first protective structure 130 has an opening OP. A portion of or all an upper surface 120S1 of the second electrode 120 may be exposed through the opening OP; in other words, the first protective structure 130 may contact or may not contact the upper surface 120S1 of the second electrode 120. As shown in FIG. 1A, the first protective structure 130 may cover a portion of the first upper surface S1, the first side surface S3, and the second side surface S4, and the first protective structure 130 may not cover the upper surface 120S1 of the second electrode 120. The first protective structure 130 may be continuously disposed over the first upper surface S1, the first side surface S3, and the second side surface S4. The first protective structure 130 may be a single-layer or multilayer structure and may include a dielectric material, such as an oxide, a nitride, or a fluoride. In some embodiments, the oxide may be silicon oxide (SiOx) or aluminum oxide (AlOx), the nitride may be silicon nitride (SiNx) or aluminum nitride (AlN), and the fluoride may be magnesium fluoride (MgFx). The first protective structure 130 may optionally include a reflective structure. In some embodiments, the reflective structure may include a distributed Bragg reflector (DBR) structure formed by alternately stacking two or more materials having different refractive indices.

The semiconductor device 10 may optionally include an electrode pad 150. The electrode pad 150 may be used to form an electrical connection and/or a physical connection with an external circuit (e.g., a circuit board). The electrode pad 150 may be filled in the opening OP and cover the second electrode 120. As shown in FIG. 1A, the electrode pad 150 may directly contact the upper surface 120S1 and the side surface 120S2 of the second electrode 120, a side surface 100a2S of the first contact layer 100a2, and a portion of the first upper surface S1. In some embodiments, the electrode pad 150 may directly contact the upper surface 120S1 of the second electrode 120 while not directly contacting the side surface 120S2, the side surface 100a2S, and/or the portion of the first upper surface S1. The electrode pad 150 may cover a portion of the first protective structure 130. In some embodiments, in the cross-sectional view, a surface 150S of the electrode pad 150 may be arcuate. The electrode pad 150 may alternatively have other cross-sectional shapes, such as a trapezoid or a rectangle. The electrode pad 150 may include a metal and/or an alloy. In some embodiments, a side surface of the first electrode 110 may be covered by the first protective structure 130.

As shown in FIG. 1B, the semiconductor device 20 may have a structure and materials similar to those of the semiconductor device 10. In some embodiments, the semiconductor device 20 further includes a second protective structure 140 formed between the first upper surface S1 and the first protective structure 130. The second protective structure 140 may be continuously disposed over the first upper surface S1, the side surface of the first contact layer 100a2, and the side surface and upper surface of the second electrode 120. The second protective structure 140 may be a single-layer or multilayer structure and may include dielectric materials, such as oxides, nitrides, or fluorides. In some embodiments, the second protective structure 140 includes a reflective structure, and the reflective structure may include a DBR structure formed by alternately stacking two or more semiconductor materials having different refractive indices or a metallic mirror. In some embodiments, the metallic mirror may include silver (Ag). In the embodiments of which the second protective structure 140 is a multilayer structure, the second protective structure 140 may include aluminum oxide, silicon oxide, and a DBR structure to enhance device protection and provide a reflective function to increase light-emitting efficiency.

In some embodiments, the first protective structure 130 may not include a reflective structure, and the second protective structure 140 includes a reflective structure. When the second protective structure 140 includes the reflective structure, the occurrence of peeling of the reflective structure can be reduced by forming the second protective structure 140 on the first upper surface S1 without forming it on the first side surface S3 and the second side surface S4, thereby improving structural stability. In some embodiments, portions of the first upper surface S1 not covered by the second electrode 120 can be covered by the second protective structure 140, thereby increasing the reflective area and enhancing reflection efficiency. As shown in FIG. 1B, in some embodiments, the second protective structure 140 and the first protective structure 130 may jointly define the opening OP. As shown in FIG. 1B, the electrode pad 150 may cover a portion of the first protective structure 130 and a portion of the second protective structure 140. For example, the electrode pad 150 may directly contact side surfaces of the first protective structure 130 and the second protective structure 140 that define the opening OP.

The semiconductor device 10′ of FIG. 1C has a structure and materials similar to those of the semiconductor device 10 shown in FIG. 1A. In some embodiments, the second portion 100b of the semiconductor device 10′ further includes a third side surface S5. Similarly, the semiconductor device 20′ of FIG. 1D has a structure and materials similar to those of the semiconductor device 20 shown in FIG. 1B. In some embodiments, the second portion 100b of the semiconductor device 20′ further includes the third side surface S5. As shown in FIGS. 1C and 1D, the third side surface S5 may be directly connected to the second side surface S4. Relative to the first lower surface S2, the first side surface S3, the third side surface S5, and the second side surface S4 may each be inclined at different angles. In some embodiments, the third side surface S5 may include a bottom surface of the first protective structure 130, an inclined side surface of the second contact layer 100b2, and a side surface of the first electrode 110; in other words, the bottom surface of the first protective structure 130, the inclined side surface of the second contact layer 100b2, and the side surface of the first electrode 110 may be substantially coplanar. In the cross-sectional view, a first imaginary line La extending along the first lower surface S2 and a fourth imaginary line Ld extending along the third side surface S5 define a third included angle θ3. In some embodiments, the third included angle θ3 is an acute angle and may be different from the first included angle θ1. In some embodiments, the third included angle θ3 may be ranging from 25° to 60° (e.g., ranging from 35° to 45°).

FIG. 1E and FIG. 1F respectively show schematic top and perspective views of a semiconductor device according to some embodiments of the present disclosure. In a top view, the semiconductor device 30 may be rectangular or square. In some embodiments, the semiconductor device 30 may alternatively be circular or other shapes. In some embodiments, a top-plan area of the semiconductor device 30 is not greater than 10000 μm², such as ranging from 1 μm² to 5000 μm² (e.g., 100 μm², 625 μm², 1250 μm², 2000 μm², or 2500 μm²). In some embodiments, in the top view, a diagonal length DL of the semiconductor device 30 may be greater than 1 μm and less than 100 μm, or further less than 50 μm to achieve the miniaturization of the device. Specifically, FIG. 1E may be a schematic top-plan view of the semiconductor devices 10, 10′, 20, or 20′; in other words, FIGS. 1A to 1D may be schematic cross-sectional views of the structure shown in FIG. 1E taken along line X-X′. FIG. 1F may be a schematic perspective view of the semiconductor devices 10 or 20.

As shown in FIGS. 1E and 1F, since the first protective structure 130 covers the epitaxial structure 100, the first protective structure 130 may include an upper surface S1′ corresponding to the first upper surface S1, a plurality of side surfaces S3′, and a plurality of side surfaces S4′. The upper surface S1′ is directly connected to each side surface S3′, and each side surface S3′ is directly connected to a respective side surface S4′. The electrode pad 150 covers a portion of the upper surface S1′. In the top view, the semiconductor device 30 may have a symmetrical structure. In some embodiments, the epitaxial structure 100 can be surrounded by the electrode pad 150, the first electrode 110, and the first protective structure 130 without being exposed, thereby providing sufficient protection.

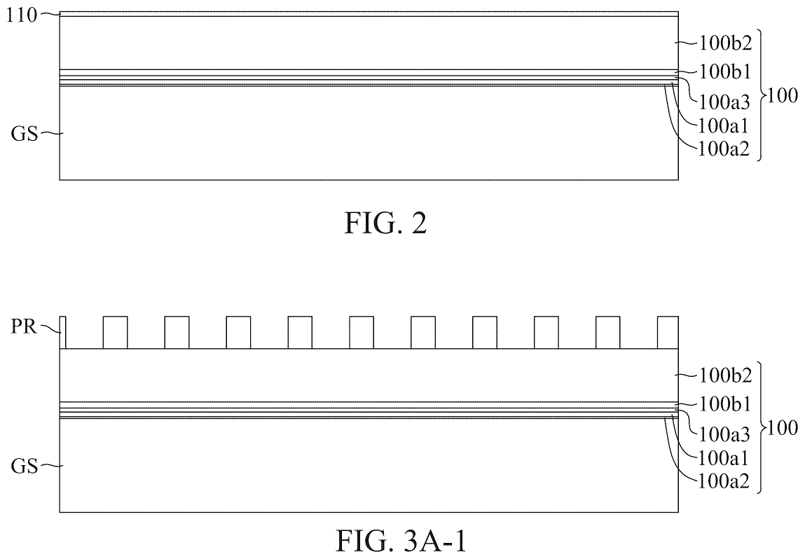

Referring to FIG. 2 to FIG. 14B. First, a growth substrate GS is provided, and an epitaxial structure 100 is formed on the growth substrate GS (as shown in FIG. 2). The growth substrate GS may include gallium arsenide (GaAs), gallium phosphide (GaP), sapphire (Al2O3), gallium nitride (GaN), or indium phosphide (InP). In some embodiments, before forming the epitaxial structure 100, a buffer layer (not shown) may be formed on the growth substrate GS to reduce defects in the epitaxial structure 100. The epitaxial structure 100 may sequentially include a first contact layer 100a2, a first cover layer 100a1, an active region 100a3, a second cover layer 100b1, and a second contact layer 100b2. The epitaxial structure 100 may further optionally include an etch stop layer (not shown) disposed between the growth substrate GS and the first contact layer 100a2 to protect the epitaxial structure 100 during removal of the growth substrate GS. In some embodiments, the etch stop layer may include indium gallium arsenide (InGaAs) or indium gallium phosphide (InGaP). In some embodiments, each layer of the epitaxial structure 100 may be formed by liquid phase epitaxy (LPE), molecular beam epitaxy (MBE), chemical beam epitaxy (CBE), metal-organic chemical vapor deposition (MOCVD), or hydride vapor phase epitaxy (HVPE).

Next, a first electrode 110 is formed on the second contact layer 100b2. To enhance the brightness of the semiconductor device, roughening may be employed to improve light extraction efficiency. For example, the second contact layer 100b2 may be further patterned to reduce light absorption by the second contact layer 100b2 and to increase the light-emitting surface of the semiconductor device, thereby improving light extraction efficiency. Alternatively, the second contact layer 100b2 and the first electrode 110 may be patterned to reduce light absorption by both the second contact layer 100b2 and the first electrode 110.

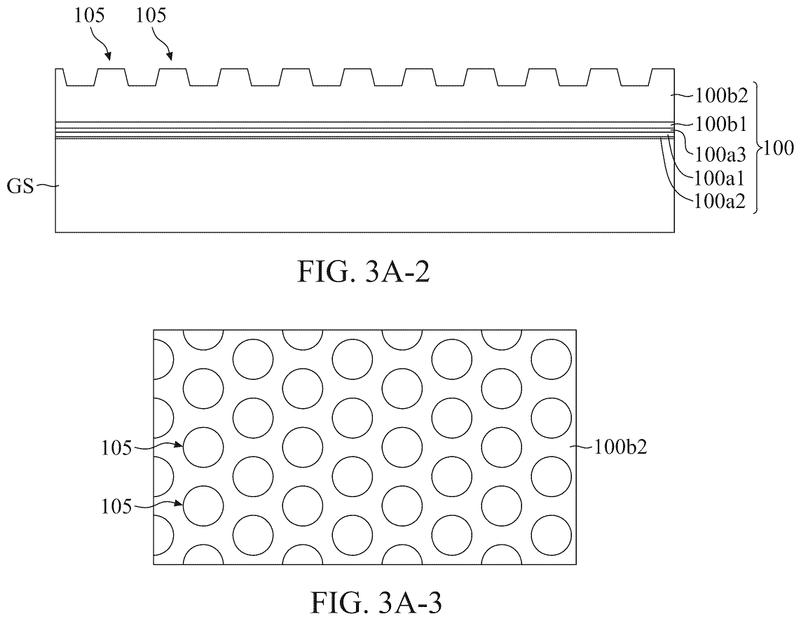

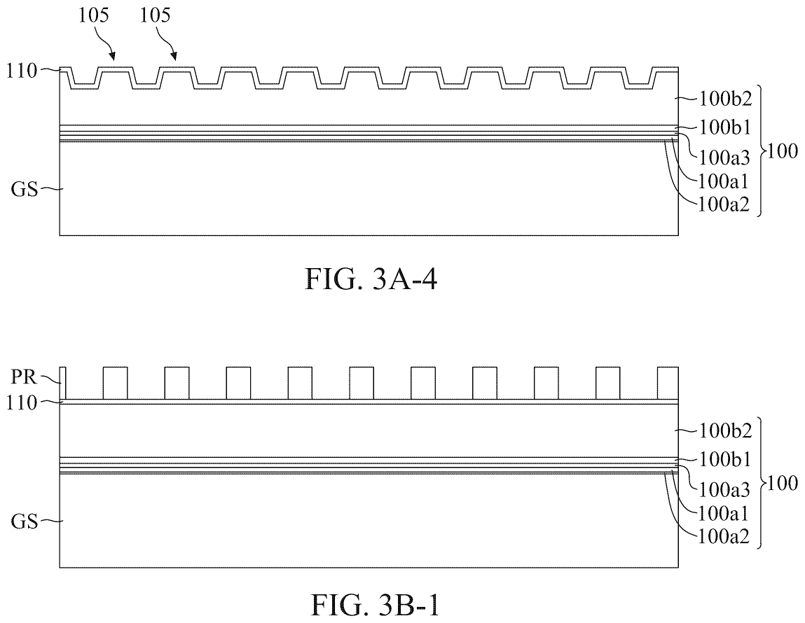

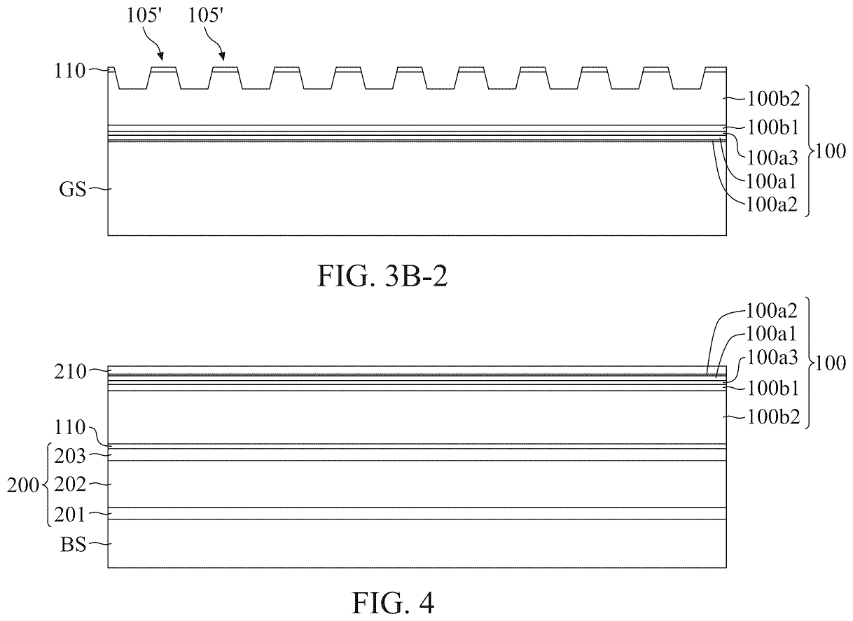

In some embodiments, the second contact layer 100b2 may be patterned before forming the first electrode 110 to improve light extraction efficiency of the semiconductor device. As shown in FIGS. 3A-1 to 3A-4, a mask layer PR is formed on the second contact layer 100b2, and the mask layer PR is used to pattern the second contact layer 100b2 to form a plurality of protrusions 105. Each of the plurality of protrusions 105 may be rectangular, trapezoidal, cylindrical, square, or irregular in shape. A top view of the patterned second contact layer 100b2 may be shown in FIG. 3A-3. The diameter of each of the plurality of protrusions 105 may be not less than 1/100 and not greater than 1/10 of a length or a width of the semiconductor device. In some embodiments, the diameter of each of the plurality of protrusions 105 may be ranging from 0.5 μm to 3 μm (e.g., ranging from 1 μm to 2.5 μm). The pitch between two adjacent protrusions 105 in the plurality of protrusions 105 may be ranging from 0.5 μm to 5 μm (e.g., ranging from 1 μm to 4 μm). Then, as shown in FIG. 3A-4, the first electrode 110 is formed on the patterned second contact layer 100b2 to cover an upper surface of the second contact layer 100b2, and an ohmic contact may be formed. As shown in FIG. 3A-3, the first electrode 110 may directly contact upper and side surfaces of each of the plurality of protrusions 105, and portions of the upper surface of the second contact layer 100b2 located between two adjacent protrusions 105.

In some embodiments, after forming the first electrode 110, the first electrode 110 and the second contact layer 100b2 may be patterned to improve light extraction efficiency of the semiconductor device. As shown in FIGS. 3B-1 and 3B-2, a mask layer PR is formed on the first electrode 110, and the mask layer PR is used to pattern the first electrode 110 and the second contact layer 100b2 to form a plurality of protrusions 105′. After patterning, the first electrode 110 remains only on upper surfaces of the plurality of protrusions 105′. The diameters and pitches of the plurality of protrusions 105′ may be made with reference to the description of the plurality of protrusions 105 and are not repeated here. Since the first electrode 110 and the second contact layer 100b2 are patterned before the first electrode 110 is formed, the first electrode 110 and the second contact layer 100b2 can first establish an ohmic contact, and the first electrode 110 can serve as a protective layer for the second contact layer 100b2 during the patterning process for forming the plurality of protrusions 105′.

Next, continuing from the structure shown in FIG. 2 and referring to FIG. 4. After forming the first electrode 110, the epitaxial structure 100 and the first electrode 110 may be connected to a bonding substrate BS via a bonding structure 200, and the growth substrate GS may be removed and the structure flipped. In some embodiments, the growth substrate GS may be removed by etching or laser lift-off (LLO). In some embodiments, the bonding step and subsequent processes may be performed in the presence of the plurality of protrusions 105 or the plurality of protrusions 105′. Specifically, the bonding structure 200 covers the plurality of protrusions 105 and fills or completely fills the spaces between the plurality of protrusions 105 to connect the epitaxial structure 100 to the bonding substrate BS. After that, the growth substrate GS may be removed and the structure flipped.

As shown in FIG. 4, after bonding, the first electrode 110 is located closer to the bonding substrate BS than the epitaxial structure 100. The bonding substrate BS may be made of sapphire, germanium, or silicon. The bonding structure 200 may be a single-layer or multi-layer structure. In some embodiments, the bonding structure 200 sequentially includes a first bonding layer 201 adjacent to the bonding substrate BS, a second bonding layer 202 on the first bonding layer 201, and a third bonding layer 203. A thickness of the second bonding layer 202 may be greater than a thickness of the first bonding layer 201 and a thickness of the third bonding layer 203.

The material of the second bonding layer 202 may be different from the material of the first bonding layer 201 and the material of the third bonding layer 203, while the first bonding layer 201 and the third bonding layer 203 may be formed of the same material. In some embodiments, the first bonding layer 201 and the third bonding layer 203 may include oxides or nitrides, and the second bonding layer 202 may include a polymer (e.g., polyimide, benzo cyclobutene (BCB), perfluorocyclobutane (PFCB), SU-8, epoxy, acrylic resin, cyclic olefin polymer (COC), polymethyl methacrylate (PMMA), polyethylene terephthalate (PET), polycarbonate (PC), polyetherimide, or a fluorocarbon polymer). In some embodiments, the bonding structure 200 is a single-layer structure and may include the polymer.

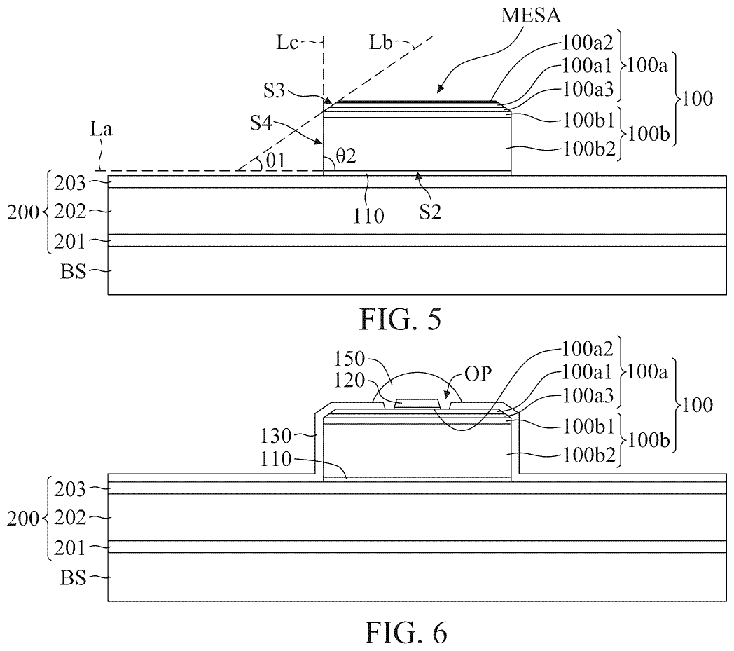

As shown in FIG. 5, portions of the epitaxial structure 100 and portions of the first electrode 110 may be removed to form a mesa platform (i.e. platform MESA) as shown in FIG. 5. In other words, the platform MESA may include the epitaxial structure 100 and the first electrode 110. The removal process may be performed by dry etching or wet etching. In some embodiments, since the platform MESA may be formed via a single-step removal process, misalignment caused by limitations in the precision of equipment such as exposure tools can be avoided, which is advantageous when device miniaturization is required. Since the sidewalls of the formed platform MESA have an inclined angle (e.g., the first included angle θ1 formed by the first imaginary line La and the second imaginary line Lb), the subsequently formed first protective structure 130 can more readily cover the epitaxial structure 100. In some embodiments, a protective layer 210 may optionally be formed on the first contact layer 100a2 (as shown in FIG. 4) to prevent damage to the epitaxial structure 100 during formation of the platform MESA before the removal process. After forming the platform MESA, the protective layer 210 may be further removed.

After that, as shown in FIG. 6, a second electrode 120 may be formed on the first contact layer 100a2. In some embodiments, portions of the first contact layer 100a2 that do not overlap the second electrode 120 in the vertical direction may be further removed to form a patterned first contact layer 100a2. In some embodiments, the first contact layer 100a2 may not be patterned, and portions of the first contact layer 100a2 that do not overlap the second electrode 120 in the vertical direction may be retained. In some embodiments, the second electrode 120 may be formed by physical vapor deposition (PVD), such as evaporation or sputtering. Next, a first protective structure 130 covering the platform MESA and the second electrode 120 may be formed, and a portion of the first protective structure 130 is removed to form an opening OP that exposes the second electrode 120. Then, the opening OP is filled with an electrode pad 150 to cover the second electrode 120. The first protective structure 130 may be formed by chemical vapor deposition (CVD), such as plasma-enhanced chemical vapor deposition (PECVD) or atomic layer deposition (ALD). The electrode pad 150 may be formed by physical vapor deposition (PVD), such as evaporation or sputtering.

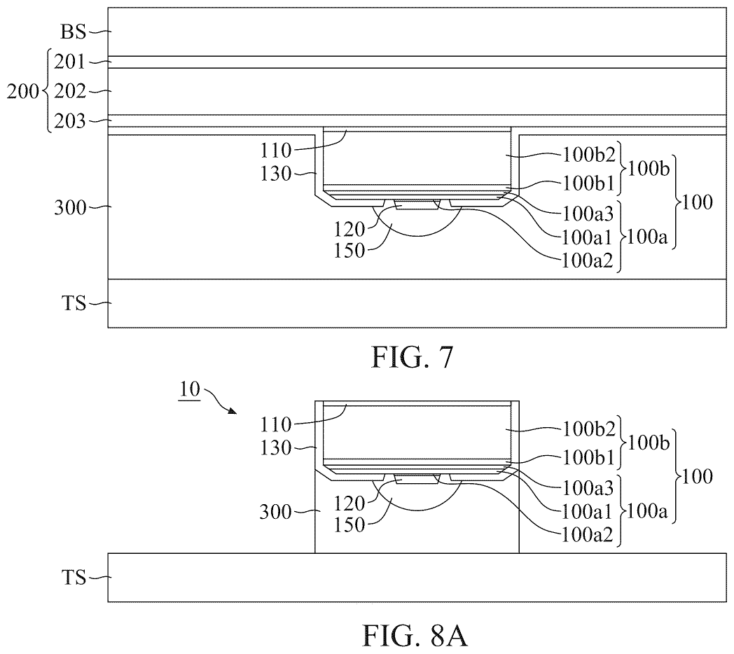

Referring to FIG. 7, subsequently, the epitaxial structure 100 and the structures formed thereon may optionally be attached to a temporary or permanent substrate TS via an adhesive structure 300. The adhesive structure 300 may include polyimide, benzo cyclobutene (BCB), epoxy resin, silicone resin, acrylic resin, or polyester. The temporary or permanent substrate TS may include sapphire, germanium, silicon, or glass.

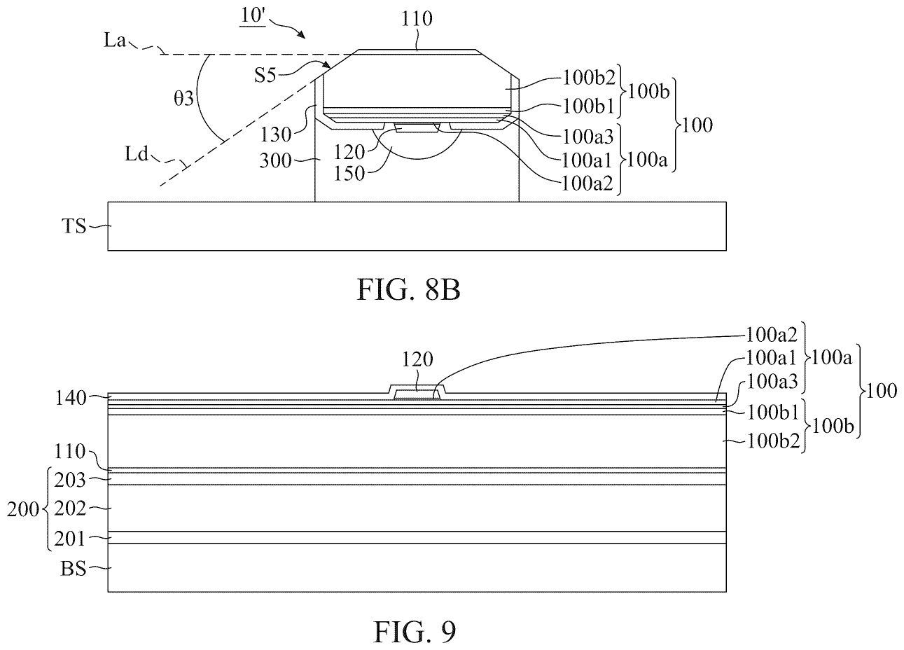

After that, the bonding substrate BS, the bonding structure 200, a portion of the first protective structure 130, and a portion of the adhesive structure 300 may optionally be removed to form the structure shown in FIG. 8A. For example, the bonding substrate BS and the bonding structure 200 may be removed by etching or laser lift-off (LLO), and the portion of the first protective structure 130 and the portion of the adhesive structure 300 are removed by etching. Accordingly, the semiconductor device 10 shown in FIG. 1A, which is connected to the temporary or permanent substrate TS via the adhesive structure 300, may be formed. In some embodiments, the remaining adhesive structure 300 may be coplanar with the insulating structure (i.e. the first protective structure 130) that covers the second side surface S4 (as shown in FIG. 8A) or may be non-coplanar. In some embodiments, during the substrate transfer process, the first protective structure 130 covering the epitaxial structure 100 provides effective protection.

In some embodiments, a portion of the second portion 100b of the epitaxial structure 100 may be further removed by etching. As shown in FIG. 8B, an inclined side surface (i.e. the third side surface S5) may further be formed in the second portion 100b, thereby obtaining the semiconductor device 10′ as shown in FIG. 1C. Since the second portion 100b of the semiconductor device 10′ has an inclined angle (e.g., the third included angle θ3 formed by the first imaginary line La and the fourth imaginary line Ld), it is advantageous for the formation of subsequent insulating or other connection structures (not shown), making them easier to cover the semiconductor device 10′. In some embodiments, the portion of the first electrode 110 and the portion of the first protective structure 130 may be concurrently removed while the portion of the second portion 100b is being removed. The structure shown in FIG. 8B may further undergo processes such as transfer, removal of the adhesive structure, and/or die attach, to fix the semiconductor device to a target carrier.

Next, another method of manufacturing a semiconductor device according to the present disclosure is described with reference to FIGS. 9 to 13 and FIGS. 14A-14B. Continuing from the structure of FIG. 4, as shown in FIG. 9, a second electrode 120 may be formed on the first contact layer 100a2. The selective patterning of the first contact layer 100a2 and the method of forming the second electrode 120 may refer to the related description of FIG. 6. Then, a second protective structure 140 is formed on the second electrode 120. The second protective structure 140 may be formed by chemical vapor deposition, such as plasma-enhanced chemical vapor deposition (PECVD) or atomic layer deposition (ALD). In some embodiments, the second protective structure 140 may include aluminum oxide formed by ALD, silicon oxide formed by PECVD, and a DBR structure. By including aluminum oxide formed by ALD, the compactness (density) of the second protective structure 140 can be improved, which helps further protect the epitaxial structure 100 and increase process stability.

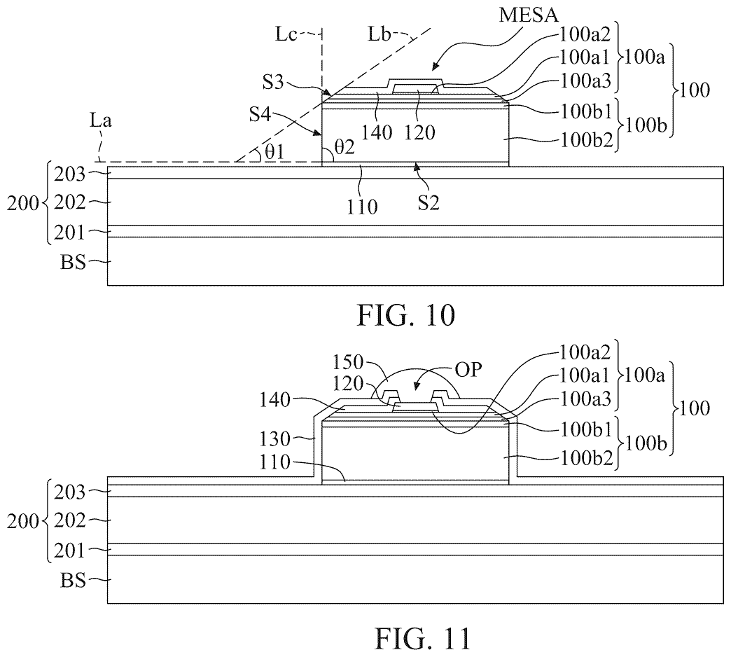

Next, portions of the second protective structure 140, the epitaxial structure 100, and the first electrode 110 are removed to form the platform MESA as shown in FIG. 10. Then, referring to FIG. 11, a first protective structure 130 is formed to cover the platform MESA, the second electrode 120, and the second protective structure 140, followed by removing portions of the first protective structure 130 and the second protective structure 140 to form an opening OP, and filling the opening OP with an electrode pad 150 that covers the second electrode 120.

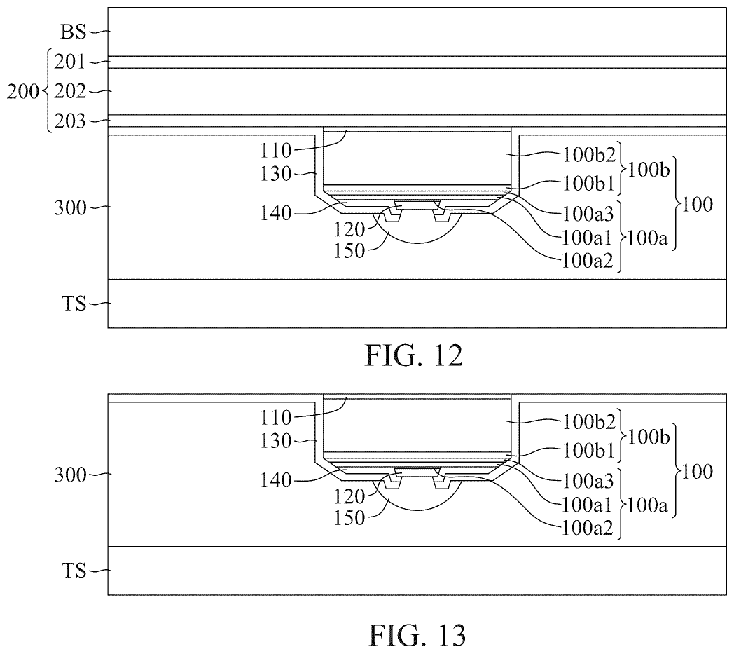

With reference to FIGS. 12, 13, and 14A, the epitaxial structure 100 and the structures formed thereon may optionally be connected to a temporary or permanent substrate TS via an adhesive structure 300, and the bonding structure 200 and the bonding substrate BS are removed. Thereafter, portions of the first protective structure 130 and portions of the adhesive structure 300 are removed by etching. In this manner, the semiconductor device 20 shown in FIG. 1B, which is connected to the temporary or permanent substrate TS via the adhesive structure 300, may be formed. In some embodiments, during the transfer process, the first protective structure 130 covering the epitaxial structure 100 provides good protection.

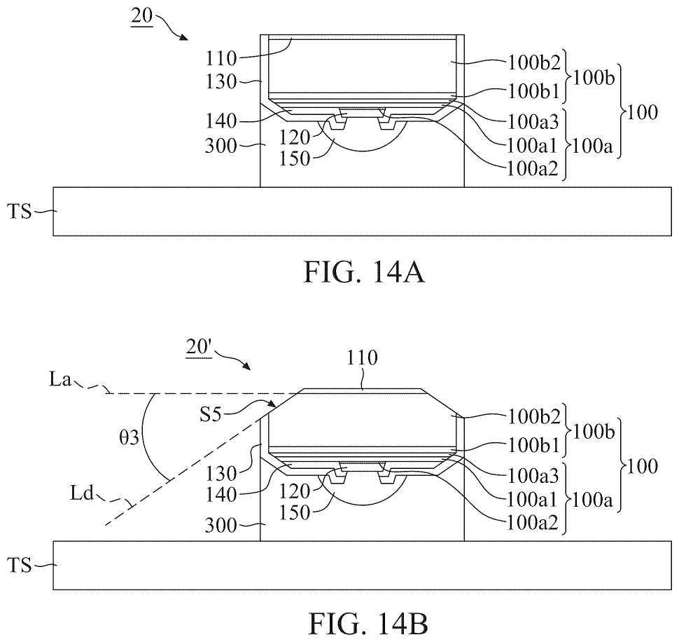

In some embodiments, a portion of the second portion 100b of the epitaxial structure 100 may be further removed by etching. As shown in FIG. 14B, an inclined side surface, i.e., the third side surface S5, may further be formed in the second portion 100b, thereby obtaining the semiconductor device 20′ as shown in FIG. 1D. Since the second portion 100b of the semiconductor device 20′ has an inclined angle (e.g., the third included angle θ3 formed by the first imaginary line La and the fourth imaginary line Ld), it is advantageous for the formation of subsequent insulating or other connection structures (not shown), making them easier to cover the semiconductor device 20′. In some embodiments, the portion of the first electrode 110 and the portion of the first protective structure 130 may be concurrently removed while the portion of the second portion 100b is being removed. The structure shown in FIG. 14B may further undergo processes such as transfer, removal of the adhesive structure, and/or die attach, to fix the semiconductor device to a target carrier.

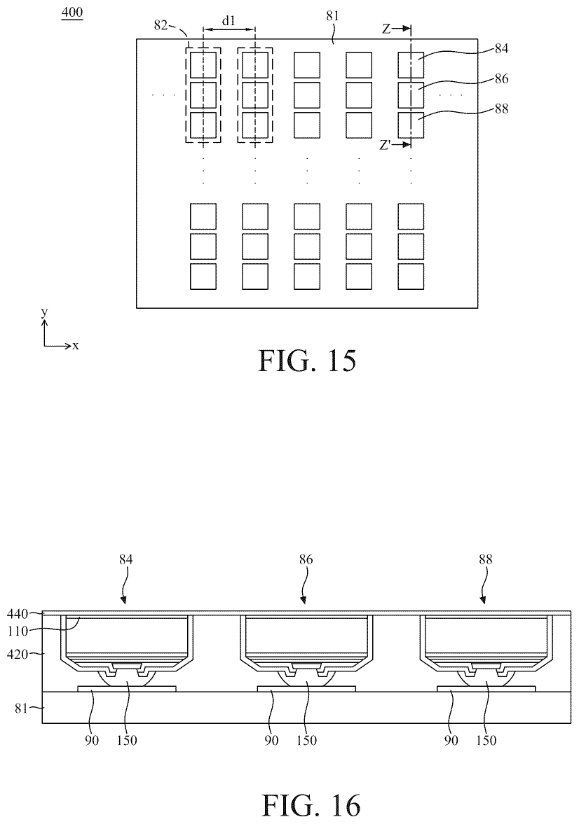

FIG. 15 shows a schematic top view of a display device 400 according to some embodiments of the present disclosure, and FIG. 16 is a schematic cross-sectional view taken along line Z-Z′ of FIG. 15. As shown in FIG. 15, the display device 400 may include a target carrier 81 and a plurality of pixel units 82 disposed on the target carrier 81. The plurality of pixel units 82 is arranged in an array along directions parallel to the x-axis and y-axis and is spaced apart by an interval d1 in the direction parallel to the x-axis. The target carrier 81 may have a single-layer or multi-layer structure. The target carrier 81 may be a printed circuit board (PCB) or a thin-film transistor (TFT) substrate. The material of the target carrier 81 may include glass, polyester, polyimide, bismaleimide triazine (BT) resin, polytetrafluoroethylene (PTFE) resin, phenolic resin, or glass fiber-reinforced epoxy (FR4). The number of pixel units 82 may be adjusted as needed. In some embodiments, the plurality of pixel units 82 included in the display device 400 may provide a resolution of 1920×1080 pixels. In some embodiments, the interval d1 may be less than 1.4 mm (for example, the interval d1 may be ranging from 0.2 mm to 1.3 mm, specifically may be 0.75 mm, 0.8 mm, 1 mm, or 1.25 mm). As shown in FIG. 16, each pixel unit 82 includes a first semiconductor device 84, a second semiconductor device 86, and a third semiconductor device 88 arranged in a direction parallel to the y-axis. Specifically, one or more of the first semiconductor device 84, the second semiconductor device 86, and the third semiconductor device 88 may be any of the semiconductor devices described in the foregoing embodiments (e.g., semiconductor devices 10, 10′, 20, 20′, or 30). In some embodiments, the first semiconductor device 84, the second semiconductor device 86, and the third semiconductor device 88 are all light-emitting devices and may respectively emit red, green, and/or blue light. In some embodiments, the first semiconductor device 84, the second semiconductor device 86, and the third semiconductor device 88 emit different light, respectively. In some embodiments, the arrangement order of these light-emitting devices may also be adjusted as required. Each pixel unit 82 may be electrically connected to circuitry (not shown) of the target carrier 81, such that the light-emitting devices therein can receive external signals and emit light according to the external signals. In some embodiments, the target carrier 81 may be bendable and, for example, can withstand a radius of curvature less than 50 mm (e.g., 25 mm or 32 mm).

FIG. 16 depicts, by way of example, the structure of the semiconductor device 10. As shown in FIG. 16, the target carrier 81 may include a conductive structure 90. The first semiconductor device 84, the second semiconductor device 86, and the third semiconductor device 88 may be connected to the conductive structure 90 via electrode pads 150, thereby being fixed to the target carrier 81. The display device 400 may further include a dielectric structure 420. The dielectric structure 420 covers the target carrier 81 and covers side surfaces of the first semiconductor device 84, the second semiconductor device 86, and the third semiconductor device 88. As shown in FIG. 16, the dielectric structure 420 fills spaces between the first semiconductor device 84, the second semiconductor device 86, and the third semiconductor device 88. In some embodiments, the dielectric structure 420 may include an opaque material or a reflective material. In some embodiments, the material of the dielectric structure 420 may include a matrix and a black material. The matrix may include silicone, epoxy, or a mixture thereof. The black material may include carbon black.

The display device 400 may further include conductive lines 440. As shown in FIG. 16, the conductive lines 440 may cover the dielectric structure 420, the first semiconductor device 84, the second semiconductor device 86, and the third semiconductor device 88, and be electrically connected to the first semiconductor device 84, the second semiconductor device 86, and the third semiconductor device 88. The conductive lines 440 may cover the dielectric structure 420. In some embodiments, for example when the first semiconductor device 84, the second semiconductor device 86, and the third semiconductor device 88 are the semiconductor devices 10 described in the foregoing embodiments, the conductive lines 440 may be in direct contact with the first electrode 110 to form electrical connections. The conductive lines 440 may be transparent and conductive, and may include a metal oxide, a metal, or an alloy. The metal oxide may be indium tin oxide (ITO), indium oxide (InO), tin oxide (SnO), cadmium tin oxide (CTO), antimony tin oxide (ATO), aluminum-doped zinc oxide (AZO), zinc tin oxide (ZTO), gallium-doped zinc oxide (GZO), indium tungsten oxide (IWO), zinc oxide (ZnO), or indium zinc oxide (IZO). The metal may include gold (Au), platinum (Pt), titanium (Ti), aluminum (Al), copper (Cu), or nickel (Ni). The alloy may include two or more of the foregoing metals, such as GeAuNi (germanium-gold-nickel), BeAu (beryllium-gold), GeAu (germanium-gold), or ZnAu (zinc-gold).

In conclusion, the present disclosure provides a semiconductor device, a method of manufacturing the same, and a semiconductor apparatus, which may achieve effects such as improving device luminous efficiency, increasing light extraction efficiency, simplifying processes, reducing costs, and/or enhancing process stability. For example, by the manufacturing method of the present disclosure, the process flow of the semiconductor device can be further simplified, and the problem of alignment offset described above can be solved; for example, the number of photolithography steps can be reduced, which is more advantageous when device miniaturization is required. Since the exterior of the epitaxial structure has a specific inclined angle, the maximum width (or vertical projected area) of the formed active region can approach or be equal to the maximum width (or vertical projected area) of the epitaxial structure, which helps maximize the area of the active region and improve luminous efficiency; an insulating structure can readily cover the epitaxial structure to provide protection; and when the semiconductor device is transferred to different substrates or carriers, the insulating structure covering the semiconductor device can also provide good protection.

Although the present disclosure has been described in considerable detail with reference to certain embodiments thereof, the disclosure is not for limiting the scope of the invention. Persons having ordinary skill in the art may make various modifications and changes without departing from the scope and spirit of the disclosure. Therefore, the scope of protection of the present disclosure shall be defined by the appended claims.

1. A semiconductor device, comprising:
an epitaxial structure comprising a first portion and a second portion adjacent to the first portion, wherein the first portion comprises a first semiconductor structure and an active region, the first portion has a first upper surface and a first side surface, the second portion comprises a second semiconductor structure and has a first bottom surface and a second side surface, and the active region is located between the first semiconductor structure and the second semiconductor structure;
a first electrode covering the first bottom surface; and
a second electrode covering the first upper surface;
wherein, in a cross-sectional view, the first side surface is directly connected to the second side surface, the active region has a first maximum width, the second portion has a second maximum width, and a ratio of the first maximum width to the second maximum width is ranging from 0.9 to 1; and
in the cross-sectional view, a first imaginary line extending along the first lower surface and a second imaginary line extending along the first side surface define a first included angle, the first imaginary line and a third imaginary line extending along the second side surface define a second included angle, the first included angle is different from the second included angle.

2. The semiconductor device according to claim 1, wherein the first included angle is an acute angle, and the second included angle is greater than the first included angle.

3. The semiconductor device according to claim 2, wherein the first included angle is ranging from 25° to 60°, and the second included angle is ranging from 75° to 100°.

4. The semiconductor device according to claim 1, wherein the first semiconductor structure comprises a first cover layer, and the first cover layer comprises a thickness ranging from 10 nm to 500 nm.

5. The semiconductor device according to claim 1, further comprising a first protective structure covering the first side surface, the second side surface and the first upper surface, wherein the first protective structure has an opening exposing the second electrode.

6. The semiconductor device according to claim 5, further comprising a second protective structure being located between the first upper surface and the first protective structure.

7. The semiconductor device according to claim 6, wherein the second protective structure comprises a distributed Bragg reflector (DBR) structure.

8. The semiconductor device according to claim 2, wherein the second portion further comprises a third side surface, the third side surface is directly connected to the second side surface.

9. The semiconductor device according to claim 8, in the cross-sectional view, wherein the first imaginary line and a fourth imaginary line extending along the third side surface define a third included angle, and the third included angle is different from the first included angle.

10. The semiconductor device according to claim 9, wherein the third included angle is an acute angle.

11. The semiconductor device according to claim 9, further comprising a first protective structure, wherein the third side surface is devoid of being covered by the first protective structure.

12. The semiconductor device according to claim 1, further comprising an electrode pad covering the second electrode.

13. The semiconductor device according to claim 12, wherein the electrode pad directly contacts the first semiconductor structure.

14. The semiconductor device according to claim 1, further comprising a plurality of protrusions formed at the first bottom surface of the second portion.

15. The semiconductor device according to claim 14, wherein the plurality of protrusions comprises a second bottom surface covered by the first electrode.

16. The semiconductor device according to claim 15, wherein the plurality of protrusions comprises a side surface covered by the first electrode.

17. A display device, comprising:
a target carrier; and
a plurality of pixel units disposed on the target carrier;
wherein at least one of the plurality of pixel units comprises a first semiconductor device, and the first semiconductor device is a semiconductor device as recited in claim 1.

18. The display device according to claim 17, wherein the target carrier comprises a conductive structure, and the at least one of the plurality of pixel units further comprises a second semiconductor device and a third semiconductor device;
the first semiconductor device, the second semiconductor device, and the third semiconductor device are connected to the conductive structure.

19. The display device according to claim 18, further comprising:
a dielectric structure covering the target carrier, side surfaces of the first semiconductor device the second semiconductor device, and the third semiconductor device; and
a conductive line covering the dielectric structure, the first semiconductor device, the second semiconductor device, and the third semiconductor device and being electrically connected to the first semiconductor device, the second semiconductor device, and the third semiconductor device.

20. The display device according to claim 18, wherein the first semiconductor device, the second semiconductor device, and the third semiconductor device emit different light.
